(19) United States
(12) Patent Application Publication
(10) Pub. No.: US 2015/0280173 A1
(43) Pub. Date: Oct. 1, 2015

(54) LIGHT EMITTING DEVICE AND MANUFACTURING METHOD OF LIGHT EMITTING DEVICE

(71) Applicant: PIONEER CORPORATION, Kawasaki-shi, Kanagawa (JP)

(72) Inventors: Kazuo Kuroda, Yokohama-shi (JP); Hiroshi Ohata, Tsurugashima-shi (JP); Toshiharu Uchida, Kawasaki-shi (JP)

(21) Appl. No.: 14/436,996

(22) PCT Filed: Oct. 26, 2012
(86) PCT No.: PCT/JP2012/077727

§ 371 Date: Apr. 20, 2015

(51) Int. Cl. H01L 51/52; H01L 51/00; H01L 51/50

(52) U.S. Cl. CPC H01L 51/5275; H01L 51/5012; H01L 51/5206; H01L 51/5253; H01L 51/0096; H01L 51/5234; H01L 2251/301; H01L 51/0045; H01L 2251/558

(57) ABSTRACT

A dielectric layer (170) faces a surface of alight transmissive electrode (120) opposite to a surface facing an organic functional layer (110). Then, a light transmissive substrate (140) faces a surface of the dielectric layer (170) opposite to a surface facing the light transmissive electrode (120). At least apart of an optical angle change unit (150) is positioned in the dielectric layer (170) in a thickness direction of the light transmissive substrate (140). Light incident on the dielectric layer (170), for example, is reflected by a side surface of the optical angle change unit (150), and thus an incident angle with respect to a first surface (141) of the light transmissive substrate (140) decreases.

### TECHNICAL FIELD

The present invention relates to a light emitting device and a manufacturing method of a light emitting device.

### BACKGROUND ART

Recently, it has been considered that a light emitting device including an organic light emitting layer is used as a light source of an illuminating device. In order to use such a light emitting device as an illuminating device, it is necessary to improve the percentage of light emitted to the outside (light extracting efficiency) among light generated by the organic light emitting layer.

As one of technologies for improving the light extracting efficiency, for example, there is a technology disclosed in Patent Documents 1 and 2. In Patent Document 1, in a display device, a metallic wedge member is embedded in a surface of a substrate on which a light emitting layer is disposed, and light is reflected on a side surface of the wedge member, and thus light extracting efficiency is improved.

In addition, in Patent Document 2, in a display device, a material having a refractive index lower than that of a substrate is embedded in a surface of the substrate on which a light emitting layer is disposed, and a low refractive index material layer is formed. Thus, light is reflected on a side surface of the low refractive index material layer, and thus light extracting efficiency is improved.

### RELATED DOCUMENT

### Patent Document

[Patent Document 1] Japanese Patent No. 3573393

[Patent Document 2] Japanese Laid-open patent publication No. 2009-110873

### DISCLOSURE OF THE INVENTION

In the technology disclosed in Patent Documents 1 and 2, it is necessary to form a concave portion for embedding the wedge member or the low refractive index material layer in the substrate. As a material of the substrate of the light emitting device, a material which is chemically and physically stable is used. For this reason, efficiency for forming the concave portion in the substrate decreases.

An example of an object of the present invention is to enhance manufacturing efficiency of a light emitting device while improving light extracting efficiency of the light emitting device.

The invention according to claim 1 is a light emitting device including an organic functional layer which includes at least a light emitting layer; a light transmissive electrode which faces one surface of the organic functional layer, and transmits light emitted by the light emitting layer; a dielectric layer which faces a surface of the light transmissive electrode opposite to a surface facing the organic functional layer, and transmits the light emitted by the light emitting layer; a light transmissive substrate of which a first surface faces a surface of the dielectric layer opposite to a surface facing the light transmissive electrode, and which transmits the light emitted by the light emitting layer, and emits the light from a second surface opposite to the first surface; and an optical angle change unit of which at least a part is positioned in the dielectric layer, and which decreases an incident angle of light incident on the dielectric layer with respect to the first surface.

The invention according to claim 8 is a light emitting device including an organic functional layer which includes at least a light emitting layer; a light transmissive electrode which faces one surface of the organic functional layer, and transmits light emitted by the light emitting layer; a dielectric layer which faces a surface of the light transmissive electrode opposite to a surface facing the organic functional layer, and transmits the light emitted by the light emitting layer; a light transmissive substrate of which a first surface faces a surface of the dielectric layer opposite to a surface facing the light transmissive electrode, and which transmits the light emitted by the light emitting layer, and emits the light from a second surface opposite to the first surface; and an optical angle change unit of which at least a part is positioned in the dielectric layer, and at least apart of a side surface is inclined in a direction facing the light transmissive substrate, and which reflects light by the side surface.

The invention according to claim 9 is a manufacturing method of a light emitting device including a step of forming a light transmissive dielectric layer on a first surface of a light transmissive substrate including the first surface and a second surface which is a surface opposite to the first surface; a step of forming a concave portion in the dielectric layer; a step of forming an optical angle change unit which decreases an incident angle of light incident on the dielectric layer with respect to the first surface by embedding a conductive material in the concave portion; a step of forming a light transmissive electrode in the dielectric layer and the optical angle change unit; and a step of forming an organic functional layer including at least a light emitting layer in the light transmissive electrode.

The invention according to claim 10 is a manufacturing method of a light emitting device including a step of forming a light transmissive dielectric layer on a first surface of a light transmissive substrate including the first surface and a second surface which is a surface opposite to the first surface; a step of forming a light transmissive electrode on the dielectric layer and along an inner surface of a concave portion; a step of forming an optical angle change unit which decreases an incident angle of light incident on the dielectric layer with respect to the first surface by embedding a conductive material in the concave portion; and a step of forming an organic functional layer including at least a light emitting layer in the light transmissive electrode and the optical angle change unit.

The object described above, and other objects, characteristics, and advantages will be more obvious with reference to the following preferred embodiments and the following drawings attached thereto.

### BRIEF DESCRIPTION OF THE DRAWINGS

FIG. 1 is a cross-sectional view illustrating a configuration of a light emitting device according to an embodiment.

FIG. 2 is a diagram illustrating a planar layout of an optical angle change unit.

FIG. 3 is a diagram illustrating a first example of a layer structure of an organic functional layer.

FIG. 4 is a diagram illustrating a second example of a configuration of the organic functional layer.

FIG. 5 is a diagram for describing a manufacturing method of the light emitting device illustrated in FIG. 1.

FIG. 6 is a diagram for describing the manufacturing method of the light emitting device illustrated in FIG. 1.

FIG. 7 is a cross-sectional view illustrating a configuration of a light emitting device according to Example 1.

FIG. 8 is a plan view of the light emitting device illustrated in FIG. 7.

FIG. 9 is a cross-sectional view illustrating a light emitting device according to Example 2.

FIG. 10 is a cross-sectional view illustrating a configuration of a light emitting device according to Example 3.

FIG. 11 is a cross-sectional view illustrating a manufacturing method of the light emitting device illustrated in FIG. 10.

FIG. 12 is a cross-sectional view illustrating a configuration of a light emitting device according to Example 4.

FIG. 13 is a cross-sectional view for describing a manufacturing method of the light emitting device illustrated in FIG. 12.

FIG. 14 is a cross-sectional view illustrating a configuration of a light emitting device according to Example 5.

FIG. 15 is a diagram illustrating a modification example of a cross-sectional shape of the optical angle change unit.

FIG. 16 is a cross-sectional view illustrating a manufacturing method of the light emitting device illustrated in FIG. 14.

FIG. 17 is a cross-sectional view illustrating a manufacturing method of the light emitting device illustrated in FIG. 14.

FIG. 18 is a plan view illustrating a layout of an optical angle change unit of a light emitting device according to Example 6.

### DESCRIPTION OF EMBODIMENTS

Hereinafter, embodiments of the present invention will be described with reference to the drawings. Furthermore, in all of the drawings, the same reference numerals are applied to the same constituents, and the description thereof will not be repeated.

### Embodiment

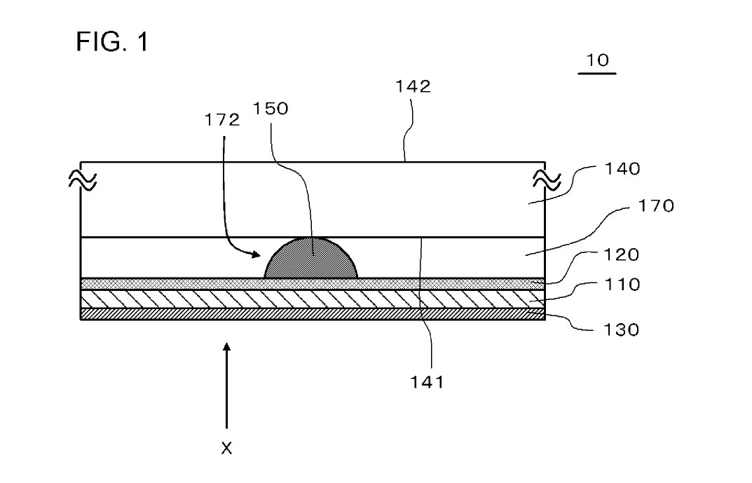

FIG. 1 is a cross-sectional view illustrating a configuration of a light emitting device 10 according to an embodiment. The light emitting device 10, for example, is able to be used as a light source of a display, an illuminating device, or an optical communication unit. The light emitting device 10 includes an organic functional layer 110, a light transmissive electrode 120, a dielectric layer 170, a light transmissive substrate 140, and an optical angle change unit 150. The dielectric layer 170, the light transmissive electrode 120, and the organic functional layer 110 are laminated on a first surface 141 of the light transmissive substrate 140 in this order. That is, the light transmissive electrode 120 faces one surface of the organic functional layer 110, and the dielectric layer 170 faces a surface of the light transmissive electrode 120 opposite to the organic functional layer 110. Then, the light transmissive substrate 140 faces a surface of the dielectric layer 170 opposite to the light transmissive electrode 120. Furthermore, other layers may be disposed between the first surface 141 and the dielectric layer 170, and another layer may also be disposed between the dielectric layer 170 and the light transmissive electrode 120. Further, another layer may also be disposed between the organic functional layer 110 and the light transmissive electrode 120.

The organic functional layer 110 includes at least a light emitting layer. All of the light transmissive electrode 120, the dielectric layer 170, and the light transmissive substrate 140 transmit at least a part of light emitted by the light emitting layer of the organic functional layer 110. A second surface 142 of the light transmissive substrate 140 opposite to the first surface 141 is a light emission surface. At least a part of the optical angle change unit 150 is positioned in the dielectric layer 170 in a thickness direction. Furthermore, in an example illustrated in this drawing, the optical angle change unit 150 is not positioned in the light transmissive substrate 140, but a tip may enter into the light transmissive substrate 140. The optical angle change unit 150 reflects light incident on the dielectric layer 170, and thus decreases an incident angle when the light is incident on the first surface 141 of the light transmissive substrate 140. Here, the incident angle is defined as an angle from a normal line of a target surface.

The light incident on the dielectric layer 170, for example, is reflected by a side surface of the optical angle change unit 150, and thus the incident angle with respect to the first surface 141 of the light transmissive substrate 140 decreases. In this case, the side surface of the optical angle change unit 150 is inclined in a direction in which at least a part of a portion positioned in the dielectric layer 170 faces the first surface 141 (an upward direction in FIG. 1).

Furthermore, light from the organic functional layer 110 may be reflected by the optical angle change unit 150 once, or may be below a critical angle while repeating reflection in an interface between the respective layers or in the optical angle change unit 150.

By disposing the optical angle change unit 150, the incident angle of the light incident on the dielectric layer 170 from the light emitting layer of the organic functional layer 110 with respect to the first surface 141 of the light transmissive substrate 140 decreases. For this reason, in light incident on the second surface 142 of the light transmissive substrate 140, a component less than a critical angle of the second surface 142 increases. As a result thereof, light extracting efficiency of the light emitting device 10 is improved.

In addition, the optical angle change unit 150 is embedded in the dielectric layer 170. In this structure, the dielectric layer 170 which is easily deformed is arranged on the light transmissive substrate 140 such as glass which is inexpensive and hard, and a shape of the dielectric layer 170 is able to be changed by a mold. For this reason, manufacturing efficiency at the time of embedding the optical angle change unit 150 increases compared to a case where the optical angle change unit 150 is embedded in the light transmissive substrate 140. Accordingly, manufacturing efficiency of the light emitting device 10 increases.

Hereinafter, a configuration of the light emitting device 10 will be described in detail.

The light transmissive substrate 140, for example, is formed of an inorganic material having light transmissivity with respect to light emitted by the light emitting layer of the organic functional layer 110. The light transmissive substrate 140, for example, is a glass substrate, and may be a resin substrate or a resin film.

The dielectric layer 170 is formed on the first surface 141 of the light transmissive substrate 140. The dielectric layer 170 is formed of a material which is different from a material of the light transmissive substrate 140 and is easily processed. For example, the dielectric layer 170 is formed of a material having a softening point lower than that of the light transmissive substrate 140. In addition, it is preferable that a refractive index of the dielectric layer 170 is approximately identical to a refractive index of the light transmissive electrode 120 (for example, within ±10%), or is greater than the refractive index of the light transmissive electrode 120. Thus, the light is easily transmitted from the light transmissive electrode 120 to the dielectric layer 170. An upper limit of the refractive index of the dielectric layer 170, for example, is 2.3, but is not limited thereto. As the material of the dielectric layer 170, for example, any one of materials configuring the respective layers of the organic functional layer 110, or glass such as oxide glass is included. In addition, as the dielectric layer 170, a thermoplastic resin (for example, acryl (PMMA), polyethylene naphthalate (PEN), polyethylene terephthalate (PET), polyvinyl chloride (PVC), oriented polypropylene (OPP), or polyethylene (PE)), a thermosetting resin (for example, dimethyl polysiloxane (PDMS)), or a thermosetting resin is able to be used. In addition, the dielectric layer 170 may be high refractive index glass using nanoparticles containing BaTiO₃. Furthermore, a thickness of the dielectric layer 170 is greater than a thickness of the light transmissive electrode 120. The thickness of the dielectric layer 170, for example, is greater than or equal to 10 times a thickness of the optical angle change unit 150.

In order to form the optical angle change unit 150 on the surface of the dielectric layer 170 facing the light transmissive electrode 120, a concave portion 172 is formed. It is preferable that the first surface 141 of the light transmissive substrate 140 is positioned in a bottom portion of the concave portion 172. Thus, it is possible to position the optical angle change unit 150 high. However, a depth of the concave portion 172 is not limited thereto.

The optical angle change unit 150 is formed by embedding a material for forming the optical angle change unit 150 in the concave portion 172. The material is a material reflecting the light emitted by the light emitting layer of the organic functional layer 110. It is preferable that the material has conductivity. The optical angle change unit 150, for example, is formed of metal. When the optical angle change unit 150 is formed of metal, the metal, for example, may be formed of a metal paste (for example, an Ag paste or an Al paste), or may be a metal line. When the metal is formed of a metal paste, the optical angle change unit 150 may include a binder. Furthermore, a material forming the optical angle change unit 150 may be a carbon material such as graphene. In addition, a conductive material configuring the optical angle change unit 150 may be in contact with the light transmissive electrode 120. For example, the concave portion 144 may not be filled with a conductive material, or a part thereof may be hollow.

In a cross-sectional shape of the concave portion 172, that is, in a cross-sectional shape of the optical angle change unit 150, a part of the side surface may be inclined toward a direction facing the light transmissive substrate 140. However, it is preferable that the side surface of the optical angle change unit 150 includes no portion directed downward in FIG. 1. In an example illustrated in this drawing, the cross-sectional shape of the optical angle change unit 150 is approximately a semicircle. However, the cross-sectional shape of the optical angle change unit 150 is not limited thereto.

In addition, the bottom portion of the concave portion 172 (that is, an end portion of the optical angle change unit 150) may be positioned in the dielectric layer 170, may be positioned in an interface between the dielectric layer 170 and the light transmissive substrate 140, and may enter into the light transmissive substrate 140.

The light transmissive electrode 120 is formed on the dielectric layer 170. In the embodiment, the light transmissive electrode 120 is continuously formed on the dielectric layer 170 and on the optical angle change unit 150. The light transmissive electrode 120, for example, is a transparent electrode formed of an indium tin oxide (ITO), an indium zinc oxide (IZO), or the like. However, the light transmissive electrode 120 may be a metal thin film which is thin to the extent of transmitting light.

As described above, the optical angle change unit 150 is formed of a conductive material. In addition, a part of the optical angle change unit 150 is in contact with the light transmissive electrode 120. In addition, as described later, the optical angle change unit 150 extends linearly when seen in a plan view. For this reason, by disposing the optical angle change unit 150, it is possible to decrease apparent resistance of the light transmissive electrode 120.

Furthermore, this effect is obtained insofar as a portion of the optical angle change unit 150 which is in contact with at least the light transmissive electrode 120 has conductivity. However, when the entire optical angle change unit 150 is formed of a conductive material, it is possible to decrease resistance of the optical angle change unit 150, and thus it is possible to particularly increase this effect. Even when plural optical angle change units 150 are dotted on the light transmissive electrode 120, electric resistance of a portion thereof is smaller than that of a portion of only the light transmissive electrode 120, and thus a resistance value decreases as a whole, and electric power transmission efficiency is improved.

In addition, the light transmissive electrode 120 is continuously formed on the optical angle change unit 150 and the dielectric layer 170. For this reason, it is possible to easily connect the optical angle change unit 150 to the light transmissive electrode 120.

In addition, the organic functional layer 110, and an electrode 130 are formed on the light transmissive electrode 120 in this order.

The organic functional layer 110 has a configuration in which a plurality of organic layers is laminated. One of these organic layers is a light emitting layer. A layer structure of the organic functional layer 110 will be described later with reference to other drawings.

The electrode 130, for example, is formed of metal such as Al or Ag, and reflects light toward the electrode 130 among light emitted by the light emitting layer of the organic functional layer 110 in a direction toward the light transmissive substrate 140.

Furthermore, a light extracting film may be disposed on the second surface 142 of the light transmissive substrate 140. By disposing the light extracting film, a part of light exceeding a critical angle is emitted to the outside, and thus an intensity of light emitted to the outside from the second surface 142 of the light transmissive substrate 140 increases.

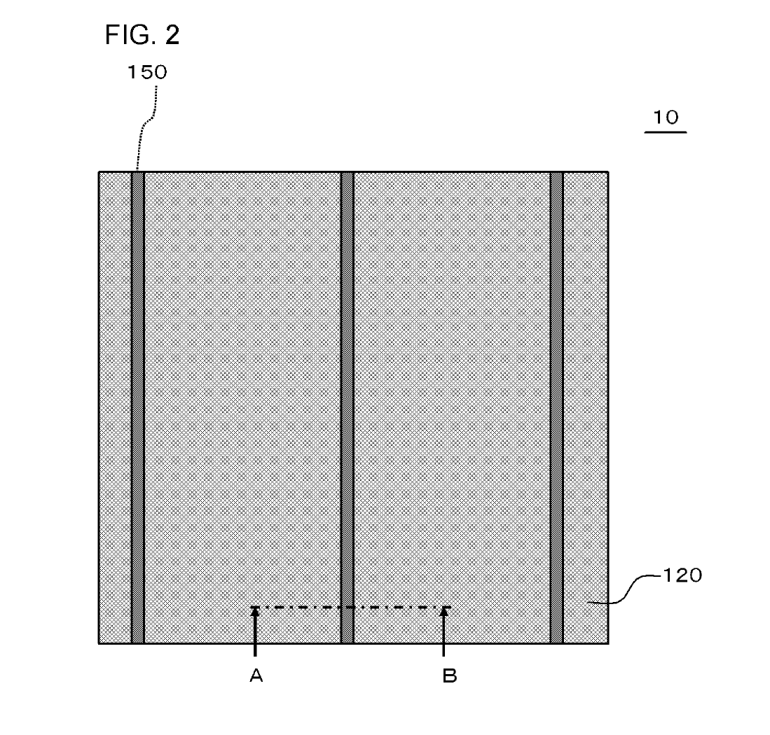

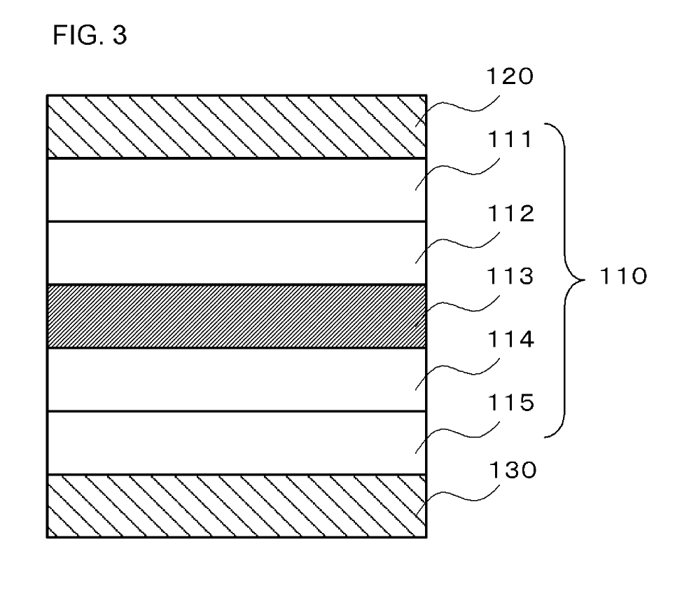

FIG. 2 is a diagram illustrating a planar layout of the optical angle change unit 150 when seen in an X direction of FIG. 1. FIG. 2 corresponds to an A-B cross-sectional surface of FIG. 3. In this drawing, for description, the optical angle change unit 150 is illustrated together with the light transmissive electrode 120.

In an example illustrated in this drawing, all of a plurality of optical angle change units 150 are linear, and are in parallel with each other. As described above, the optical angle change unit 150 functions as auxiliary wiring (a bus line) for decreasing resistance of the light transmissive electrode 120. Furthermore, the optical angle change unit 150 may be arranged at regular intervals, or may be arranged such that at least apart is arranged at intervals different from that of the other parts.

FIG. 3 is a diagram illustrating a first example of a layer structure of the organic functional layer 110. In an example illustrated in this drawing, the organic functional layer 110 has a structure in which a hole injection layer 111, a hole transport layer 112, a light emitting layer 113, an electron transport layer 114, and an electron injection layer 115 are laminated in this order. That is, the organic functional layer 110 is an organic electroluminescence light emitting layer. Furthermore, instead of the hole injection layer 111 and the hole transport layer 112, one layer having functions of these two layers may be disposed. Similarly, instead of the electron transport layer 114 and the electron injection layer 115, one layer having functions of these two layers may be disposed.

In an example illustrated in this drawing, the light emitting layer 113, for example, is a layer emitting light of a red color, a layer emitting light of a blue color, a layer emitting light of a yellow color, or a layer emitting light of a green color. In this case, in the light emitting device 10, a region including the light emitting layer 113 emitting light of a red color, a region including the light emitting layer 113 emitting light of a green color, and a region including the light emitting layer 113 emitting light of a blue color may be repeatedly disposed when seen in a plan view. In this case, when the respective regions emit light at the same time, the light emitting device 10 emits light of a white color.

Furthermore, the light emitting layer 113 may be configured to emit light of a white color by mixing materials for emitting light of a plurality of colors.

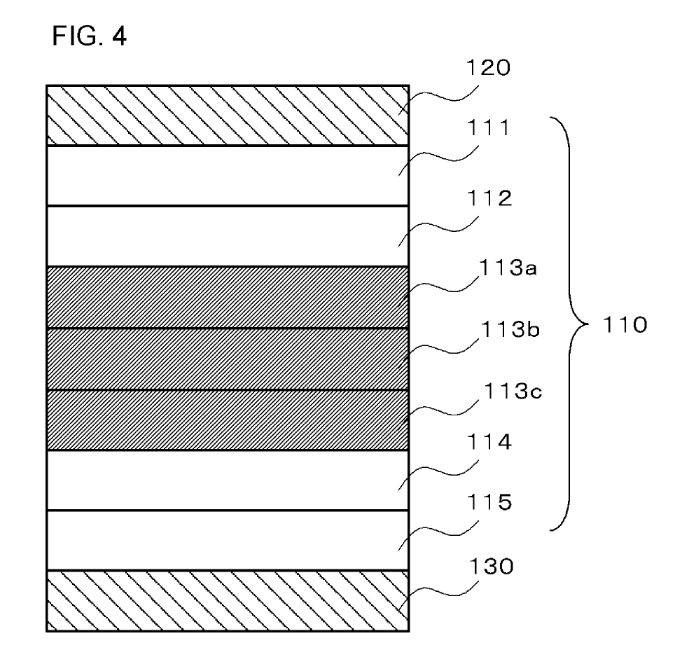

FIG. 4 is a diagram illustrating a second example of the configuration of the organic functional layer 110. In an example illustrated in this drawing, the organic functional layer 110 has a configuration in which light emitting layers 113a, 113b, and 113c are laminated between the hole transport layer 112 and the electron transport layer 114. The light emitting layers 113a, 113b, and 113c emit light of colors different from each other (for example, red, green, and blue). Then, the light emitting layers 113a, 113b, and 113c emit light at the same time, and thus the light emitting device 10 emits light of a white color.

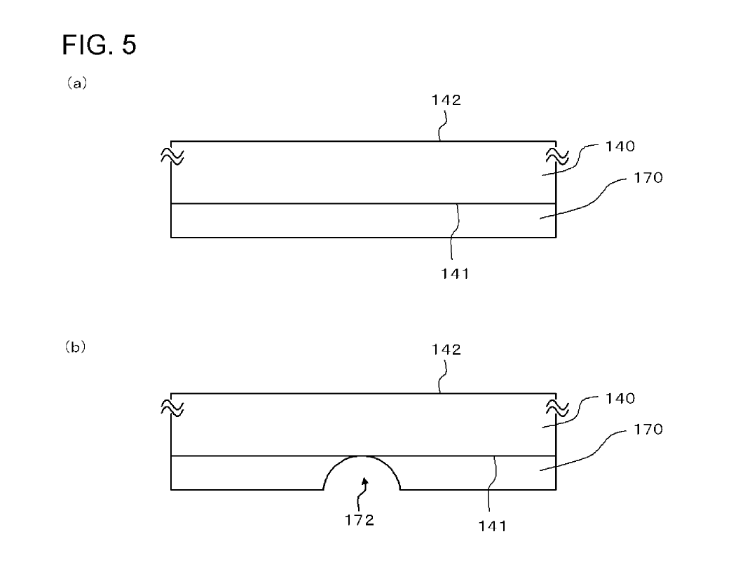

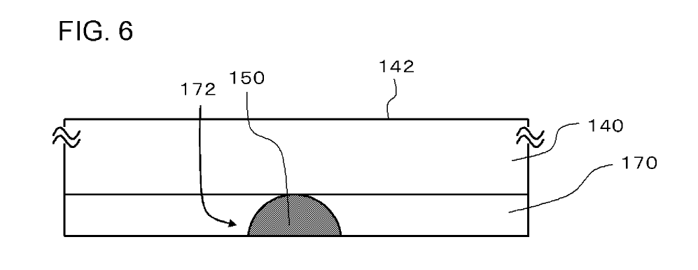

FIG. 5 and FIG. 6 are diagrams for describing a manufacturing method of the light emitting device 10 illustrated in FIG. 1. First, as illustrated in FIG. 5(a), the light transmissive substrate 140 is prepared. Subsequently, the dielectric layer 170 is formed on the first surface 141 of the light transmissive substrate 140. The dielectric layer 170, for example, may be formed by using a coating method, or may be formed by thermally compressing a sheet material which becomes the dielectric layer 170 onto the first surface 141.

Subsequently, as illustrated in FIG. 5(b), the concave portion 172 is formed by heating the light transmissive substrate 140 up to a deformable temperature (greater than or equal to softening point and less than or equal to melting point), and then pressing a mold (for example, a carbon mold). Furthermore, when the dielectric layer 170 is glass, the concave portion 172 may be formed by forming a mask pattern (for example, a resist pattern) on the dielectric layer 170, and by etching the dielectric layer 170 using this mask pattern as a mask. In this etching, for example, wet etching is used. In this case, as an etching liquid, for example, a hydrofluoric acid is used. Accordingly, the concave portion 172 is formed in the light transmissive electrode 120 and the light transmissive substrate 140. Furthermore, the concave portion 172 may be formed by shot blast (for example, sand blast, water blast, and wet blast).

Subsequently, as illustrated in FIG. 6, the optical angle change unit 150 is formed in the concave portion 172. The optical angle change unit 150, for example, is formed by the following method.

First, the concave portion 172 is filled with a conductive paste, for example, by using a screen printing method. A filling method of the conductive paste may be a method using a dispenser or an ink jet method. Subsequently, the conductive paste is heated and dried. Accordingly, the optical angle change unit 150 is formed.

After that, the light transmissive electrode 120, the organic functional layer 110, and the electrode 130 are formed on the dielectric layer 170 and on the optical angle change unit 150 in this order. The light transmissive electrode 120 and the electrode 130, for example, are formed by using a sputtering method. In addition, the organic functional layer 110 is formed by using a coating method or a vapor deposition method.

As described above, according to the embodiment, the dielectric layer 170 is formed between the light transmissive substrate 140 and the organic functional layer 110. Then, the optical angle change unit 150 is embedded in the dielectric layer 170. For this reason, it is possible to easily form the optical angle change unit 150 compared to the case where the optical angle change unit 150 is embedded in the light transmissive substrate 140. In addition, as the material of the light transmissive substrate 140, a high light transmissive material is used, and thus it is possible to increase light extracting efficiency of the light emitting device 10 compared to a case where the light transmissive substrate 140 is formed of the same material as that of the dielectric layer 170.

In addition, when the dielectric layer 170 is not disposed, among light emitted from the organic functional layer 110, a component of which an incident angle with respect to an interface between the dielectric layer 170 and the light transmissive substrate 140 is less than a critical angle is reflected by this interface. This reflected light is transmitted through the organic functional layer 110, and is further reflected by the electrode 130. The light is attenuated when passing through the organic functional layer 110, and thus when this reflection is repeated, the light emitted from the organic functional layer 110 is considerably attenuated. In contrast, in this embodiment, the dielectric layer 170 is thicker than the light transmissive electrode 120. Then, when seen in the thickness direction, the optical angle change unit 150 is disposed in approximately the entire dielectric layer 170. For this reason, the light passing through the dielectric layer 170 is more likely to be reflected by the side surface of the optical angle change unit 150. In this case, the number of times of light reciprocating between the first surface 141 and the electrode 130, that is, the number of times of the light passing through the organic functional layer 110 is able to be decreased. Accordingly, light extracting efficiency of the light emitting device 10 is able to be improved.

### EXAMPLE

### Example 1

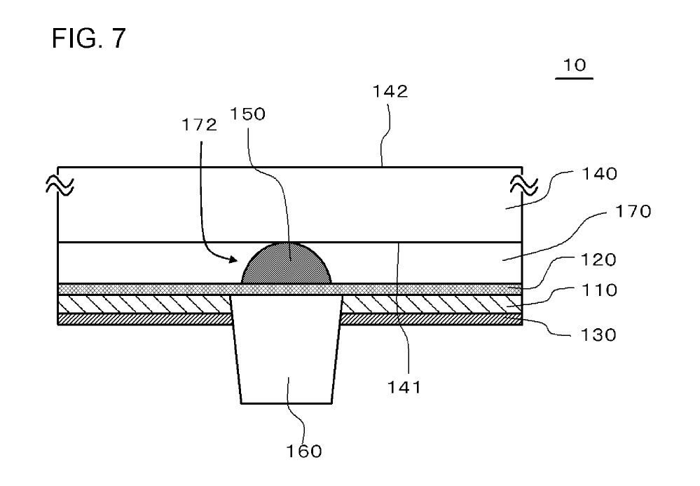

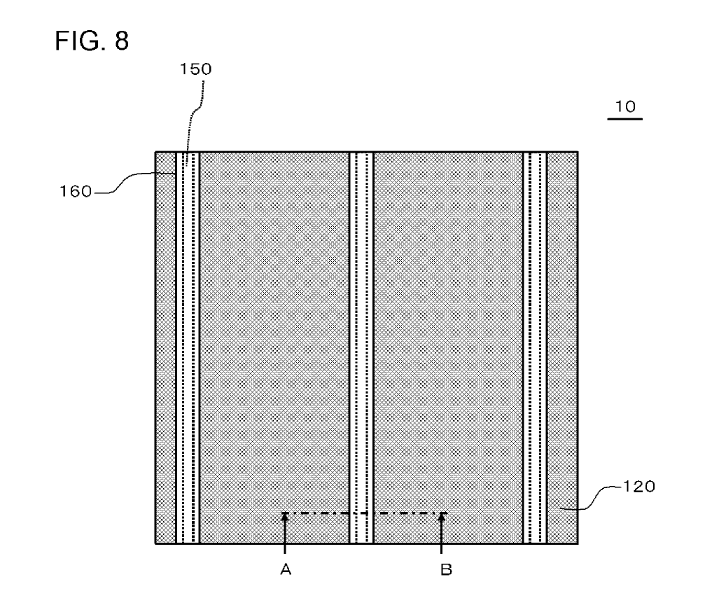

FIG. 7 is a cross-sectional view illustrating a configuration of the light emitting device 10 according to Example 1. FIG. 8 is a plan view of the light emitting device 10 illustrated in FIG. 7, and corresponds to FIG. 2 of the embodiment. The light emitting device 10 according to this example has the same configuration as that of the light emitting device 10 according to the embodiment except that a partition wall portion 160 is included.

The partition wall portion 160 is disposed on the light transmissive electrode 120, and divides the organic functional layer 110 and the electrode 130 into a plurality of regions. The respective regions divided by the partition wall portion 160 may emit light of colors different from each other, or may emit light of the same color.

The partition wall portion 160 is formed of an insulating material, for example, a photosensitive resin such as a polyimide film. Then, the optical angle change unit 150 is positioned in a position overlapping the partition wall portion 160 when seen in a plan view, and more specifically, inside the partition wall portion 160.

In an example illustrated in FIG. 8, the optical angle change unit 150 is disposed corresponding to the entire partition wall portion 160. However, some partition wall portions 160 may be without the optical angle change unit 150.

Next, a manufacturing method of the light emitting device 10 according to this example will be described. Steps until the light transmissive electrode 120 is formed are identical to that of the embodiment. The light transmissive electrode 120 is formed, then a polyimide film is formed on the light transmissive electrode 120, and then exposure and developing are performed. Accordingly, the partition wall portion 160 is formed. After that, the light transmissive electrode 120, the organic functional layer 110, and the light transmissive electrode 120 are formed.

According to this example, the same effect as that of the embodiment is able to be obtained. In addition, when the optical angle change unit 150 is disposed, a region of the first surface 141 of the light transmissive substrate 140 on which light is incident decreases when seen in a plan view. In contrast, in this example, the optical angle change unit 150 overlaps the partition wall portion 160 when seen in a plan view. In a region of the optical angle change unit 150 overlapping the partition wall portion 160 when seen in a plan view, the organic functional layer 110 is not able to be formed, and thus an intensity of incident light decreases. For this reason, when the optical angle change unit 150 overlaps the partition wall portion 160, it is possible to prevent the region of the first surface 141 of the light transmissive substrate 140 on which the light is incident from being decreased due to addition of the optical angle change unit 150.

### Example 2

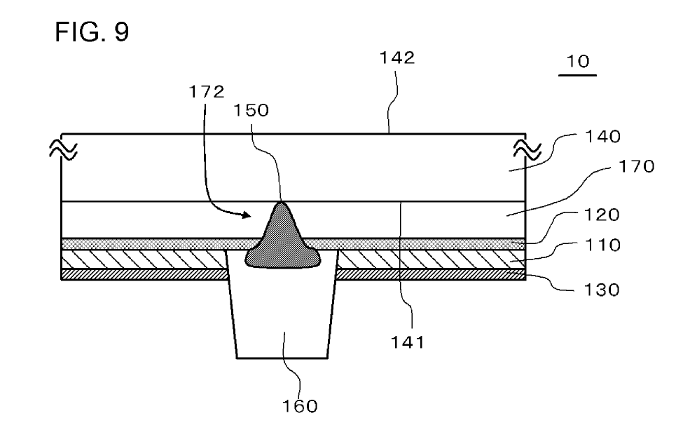

FIG. 9 is a cross-sectional view illustrating the light emitting device 10 according to Example 2. In this example, the following is different from Example 1.

First, the cross-sectional shape of the optical angle change unit 150 is different from that of Example 1. Specifically, the optical angle change unit 150 has a configuration in which a vertex of a triangle in a height direction is rounded when seen in a cross-sectional view. That is, an angle of the side surface in at least a tip portion of the optical angle change unit 150 is changed to be closer to a direction parallel with the light transmissive substrate 140 toward the light transmissive substrate 140. In addition, a connection portion between a side surface of the concave portion 172 (that is, the side surface of the optical angle change unit 150) and an upper surface of the dielectric layer 170 is rounded. Such a shape is able to be realized by adjusting a condition (for example, an etching condition) at the time of forming the concave portion 172.

Further, a part of the optical angle change unit 150 reaches the partition wall portion 160 when seen in the thickness direction. At least a part of a portion of the side surface of the optical angle change unit 150 positioned in the partition wall portion 160 is inclined in a direction facing the second surface 142.

Further, the concave portion 172 is formed from the light transmissive electrode 120 to the dielectric layer 170 when seen in the thickness direction. Then, the optical angle change unit 150 penetrates the light transmissive electrode 120. Apart of the side surface of the optical angle change unit 150 is connected to the light transmissive electrode 120.

The manufacturing method of the light emitting device 10 according to this example is identical to the manufacturing method of the light emitting device 10 according to Example 1 except that the concave portion 172 and the optical angle change unit 150 are formed after the dielectric layer 170 is formed and before the concave portion 172 is formed.

In this example, the same effect as that of the embodiment is able to be obtained. In addition, as described in the embodiment, a part of light incident on the dielectric layer 170 from the organic functional layer 110 finally becomes less than a critical angle in the interface between the dielectric layer 170 and the light transmissive substrate 140 while repeating reflection in each interface or the optical angle change unit 150. When light is reflected by a center portion of the optical angle change unit 150, the light may have an angle in which light extracting efficiency to an air layer is degraded. In contrast, in this example, the angle of the tip portion of the optical angle change unit 150 is changed to be closer to the direction parallel with the first surface 141 toward the first surface 141 of the light transmissive substrate 140. For this reason, the light reflected by the center portion of the optical angle change unit 150 reaches the tip portion of the optical angle change unit 150, and thus an incident angle of the light with respect to the first surface 141 can be made less than a critical angle of the first surface 141.

In addition, the partition wall portion 160 is formed of a material having light transmissivity with respect to the light emitted by the light emitting layer of the organic functional layer 110 and may transmit the light emitted by the light emitting layer of the organic functional layer 110. In this case, the portion of the side surface of the optical angle change unit 150 positioned in the partition wall portion 160 reflects the light incident on the partition wall portion 160, and decreases an incident angle of the light. Accordingly, an intensity of the light transmitted through the respective layers increases, and thus light extracting efficiency of the light emitting device 10 is able to be improved.

### Example 3

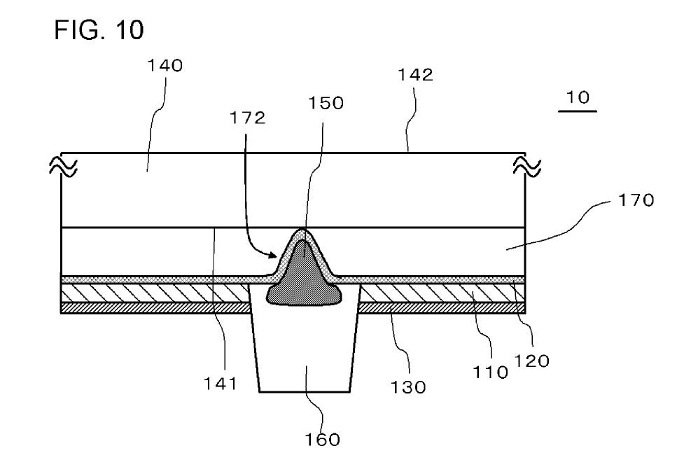

FIG. 10 is a cross-sectional view illustrating a configuration of the light emitting device 10 according to Example 3. The light emitting device 10 according to Example 3 has the same configuration as that of the light emitting device 10 according to Example 2 except for the following. First, the light transmissive electrode 120 is continuously formed on the dielectric layer 170 and along an inner wall of the concave portion 172. Then, the optical angle change unit 150 is formed on the light transmissive electrode 120 in the concave portion 172. That is, the optical angle change unit 150 is connected to the light transmissive electrode 120 in a portion of the side surface positioned in the dielectric layer 170. In addition, at least a part of a portion in the side surface of the optical angle change unit 150 which overlaps the organic functional layer 110 in the thickness direction is inclined in a direction facing the light transmissive substrate 140.

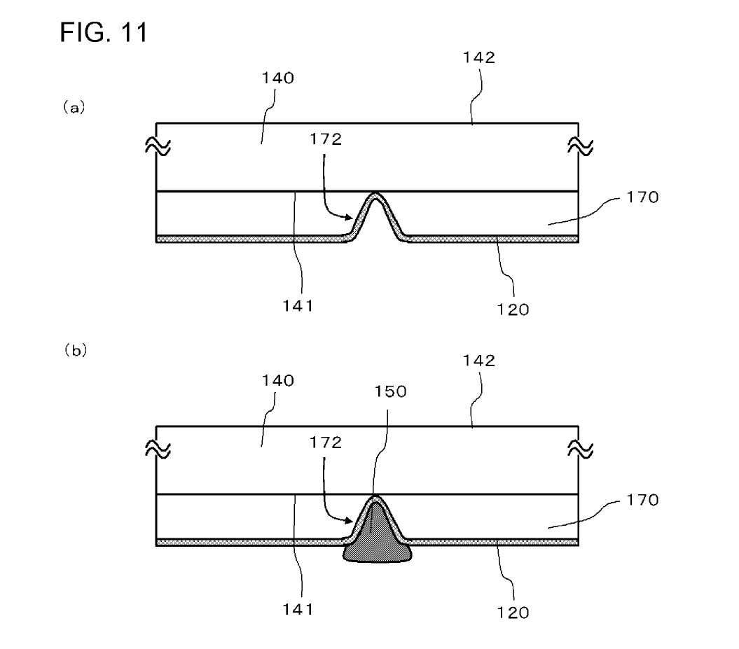

FIG. 11 is a cross-sectional view illustrating a manufacturing method of the light emitting device 10 illustrated in FIG. 10. First, as illustrated in FIG. 11(a), the dielectric layer 170 is formed on the first surface 141 of the light transmissive substrate 140, and the concave portion 172 is formed in the dielectric layer 170. Subsequently, the light transmissive electrode 120 is formed along the upper surface of the dielectric layer 170 and the concave portion 172. A forming method of the light transmissive electrode 120 is as described in the embodiment.

Subsequently, as illustrated in FIG. 11(b), the optical angle change unit 150 is formed on the light transmissive electrode 120 in the concave portion 172. A forming method of the optical angle change unit 150 is also as described in the embodiment. At this time, an upper portion of the optical angle change unit 150 (a lower portion in FIG. 11(b)) protrudes from the dielectric layer 170. This, for example, is able to be realized by building up a conductive paste using a screen or the like.

Subsequent steps are identical to that of the embodiment.

According to this example, the same effect as that of the embodiment is able to be obtained. In addition, the light transmissive electrode 120 is formed along the concave portion 172, and thus it is possible to increase a contact area between the light transmissive electrode 120 and the optical angle change unit 150. Accordingly, it is possible to decrease connection resistance between the light transmissive electrode 120 and the optical angle change unit 150.

In addition, at least a part of the portion in the side surface of the optical angle change unit 150 which overlaps the organic functional layer 110 in the thickness direction is inclined in the direction facing the light transmissive substrate 140. For this reason, light intruding inside the partition wall portion 160 from the organic functional layer 110 is reflected by the side surface of the optical angle change unit 150, and thus an incident angle with respect to the light transmissive electrode 120, the dielectric layer 170, and the light transmissive substrate 140 decreases. For this reason, light extracting efficiency of the light emitting device 10 is able to be increased.

### Example 4

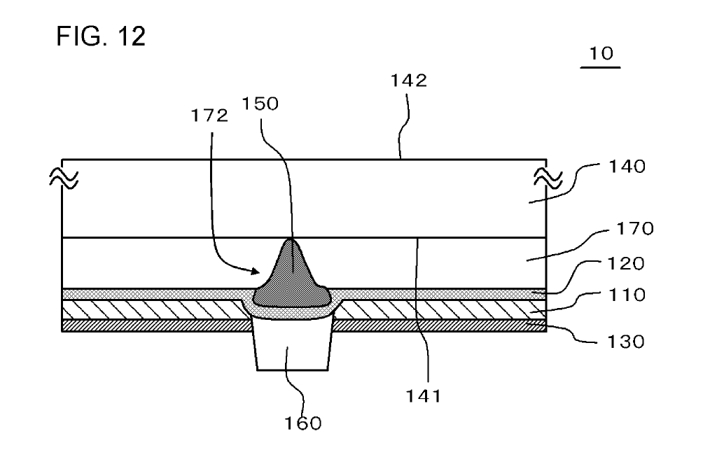

FIG. 12 is a cross-sectional view illustrating a configuration of the light emitting device 10 according to Example 4. The light emitting device 10 according to this example has the same configuration as that of the light emitting device 10 according to Example 2 except that the light transmissive electrode 120 is also formed on the optical angle change unit 150. In detail, the light transmissive electrode 120 is continuously formed from on the dielectric layer 170 to on the optical angle change unit 150.

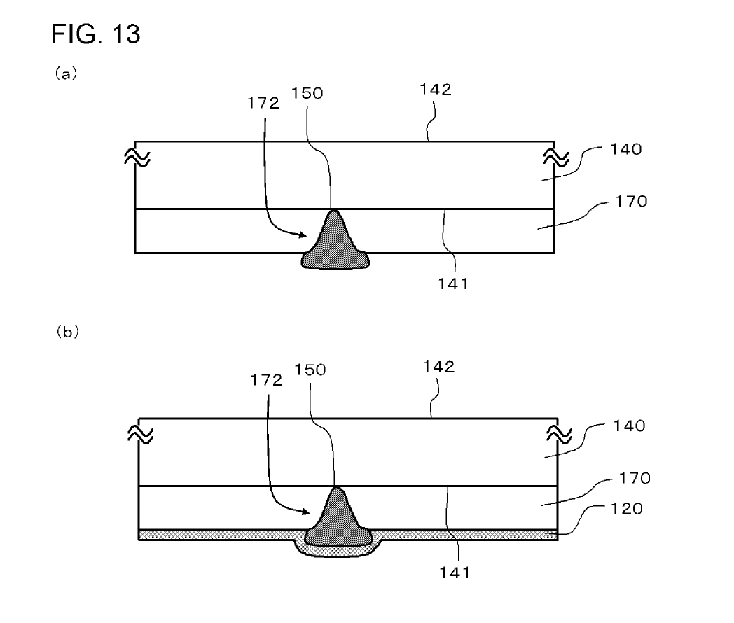

FIG. 13 is a cross-sectional view for describing a manufacturing method of the light emitting device 10 illustrated in FIG. 12. First, as illustrated in FIG. 13(a), the dielectric layer 170 is formed on the light transmissive substrate 140, and the concave portion 172 is formed in the dielectric layer 170. Subsequently, the optical angle change unit 150 is formed in the concave portion 172. A forming method of the optical angle change unit 150 is as described in the embodiment. At this time, the upper portion of the optical angle change unit 150 protrudes from the dielectric layer 170.

Next, as illustrated in FIG. 13 (b), the light transmissive electrode 120 is formed along the upper surface of the dielectric layer 170 and a portion of the optical angle change unit 150 protruding from the dielectric layer 170. A forming method of the light transmissive electrode 120 is as described in the embodiment.

Subsequent steps are identical to that of Example 1. According to this example, the same effect as that of the embodiment is able to be obtained.

### Example 5

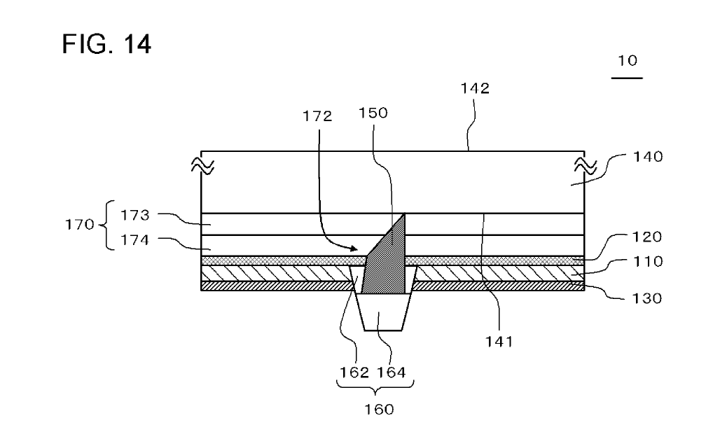

FIG. 14 is a cross-sectional view illustrating a configuration of the light emitting device 10 according to Example 5. The light emitting device 10 according to this example has the same configuration as that of the light emitting device 10 according to Example 1 except for the following.

First, the dielectric layer 170 has a configuration in which a first dielectric layer 173 and a second dielectric layer 174 are laminated on the light transmissive substrate 140 in this order. A refractive index of the first dielectric layer 173 is lower than a refractive index of the second dielectric layer 174, and is greater than a refractive index of the light transmissive substrate 140. Furthermore, in an example illustrated in this drawing, the dielectric layer 170 has a double-layer structure of the first dielectric layer 173 and the second dielectric layer 174, and may have a structure in which three or more layers are laminated. Even in this case, a refractive index of the respective layers configuring the dielectric layer 170 decreases toward the light transmissive substrate 140. That is, when seen in the entire dielectric layer 170, a refractive index of the dielectric layer 170 decreases stepwisely toward the light transmissive substrate 140.

In addition, the cross-sectional shape of the optical angle change unit 150 is different. The optical angle change unit 150 has a shape in which two side surfaces are different from each other. In an example illustrated in this drawing, both portions of the side surfaces in a left side of the drawing are inclined in the direction facing the first surface 141 of the light transmissive substrate 140. However, a portion positioned in the dielectric layer 170 is more inclined than the other portion. On the other hand, the side surface on a right side of the drawing is approximately perpendicular to the first surface 141.

In addition, the partition wall portion 160 has a configuration in which a second partition wall portion 164 is laminated on a first partition wall portion 162. The concave portion 172 is formed from the first partition wall portion 162 to the dielectric layer 170. Then, the second partition wall portion 164 is formed on the first partition wall portion 162 and on the optical angle change unit 150. As a result thereof, when seen in the thickness direction, the entire organic functional layer 110 overlaps the side surface of the optical angle change unit 150. In particular, in an example illustrated in this drawing, the entire electrode 130 overlaps the side surface of the optical angle change unit 150. Then, in this overlapping portion, the side surface of the optical angle change unit 150 is inclined in the direction facing the light transmissive substrate 140.

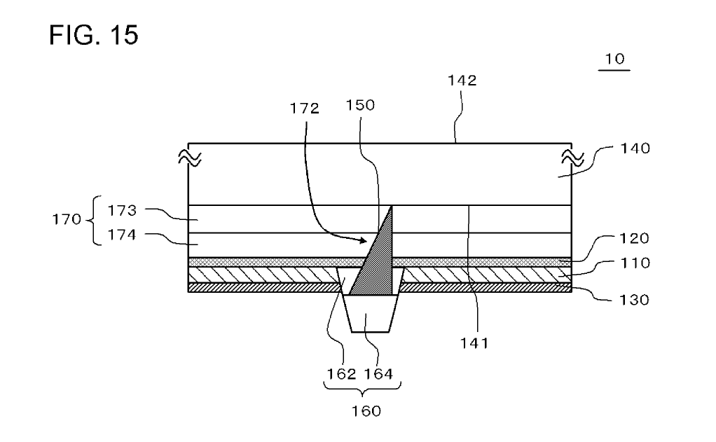

FIG. 15 is a diagram illustrating a modification example of the cross-sectional shape of the optical angle change unit 150. In an example illustrated in this drawing, the cross-sectional shape of the optical angle change unit 150 is a triangle. Then, the side surface of the optical angle change unit 150 in a right side of the drawing is approximately perpendicular to the first surface 141.

Furthermore, in both of the examples of FIG. 14 and FIG. 15, a plurality of optical angle change units 150 is arranged in parallel with each other such that the cross-sectional shape is in the same direction.

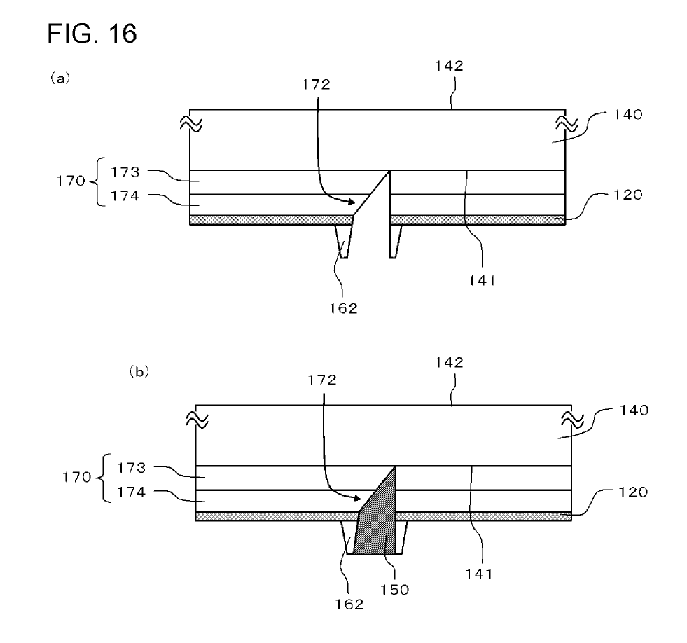

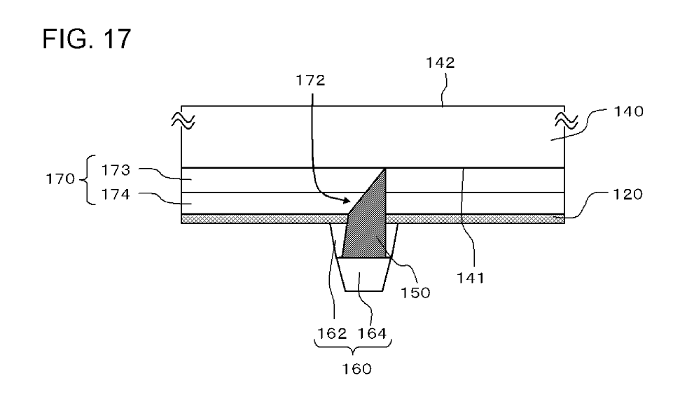

FIG. 16 and FIG. 17 are cross-sectional views illustrating a manufacturing method of the light emitting device 10 illustrated in FIG. 14. First, as illustrated in FIG. 16(a), the dielectric layer 170 and the light transmissive electrode 120 are formed on the first surface 141 of the light transmissive substrate 140 in this order, and the first partition wall portion 162 is formed on the light transmissive electrode 120. The first partition wall portion 162, for example, is formed by the same method as that of the partition wall portion 160 in Example 1.

Subsequently, a resist pattern (not illustrated) is formed on the light transmissive electrode 120 and on the first partition wall portion 162, and the first partition wall portion 162, the light transmissive electrode 120, and the dielectric layer 170 are etched by using this resist pattern. Accordingly, the concave portion 172 is formed in the first partition wall portion 162, the light transmissive electrode 120, and the dielectric layer 170.

Next, as illustrated in FIG. 16(b), the optical angle change unit 150 is formed in the concave portion 172. A forming method of the optical angle change unit 150 is as described in Example 1.

After that, as illustrated in FIG. 17, the second partition wall portion 164 is formed on the first partition wall portion 162 and on the optical angle change unit 150. The second partition wall portion 164, for example, is formed by the same method as that of the partition wall portion 160 of Example 1.

After that, the organic functional layer 110 and the electrode 130 are formed. A forming method thereof is identical to that of Example 1.

According to this example, the same effect as that of Example 1 is able to be obtained. In addition, in the thickness direction, the optical angle change unit 150 is able to overlap both of the light transmissive electrode 120 and the electrode 130. For this reason, when light is incident on the partition wall portion 160 from the organic functional layer 110, most of the light is reflected by the side surface of the optical angle change unit 150, and an incident angle with respect to the dielectric layer 170 and the light transmissive substrate 140 decreases. For this reason, light extracting efficiency of the light emitting device 10 is able to be further improved.

In addition, one of the side surfaces of the optical angle change unit 150 is approximately vertical. In this case, it is possible to increase a height of the optical angle change unit 150 (the depth of the concave portion 172). When the optical angle change unit 150 is high, light emitted by the organic functional layer 110 in the dielectric layer 170 is easily reflected by the side surface of the optical angle change unit 150. For this reason, light extracting efficiency of the light emitting device 10 further increases.

### Example 6

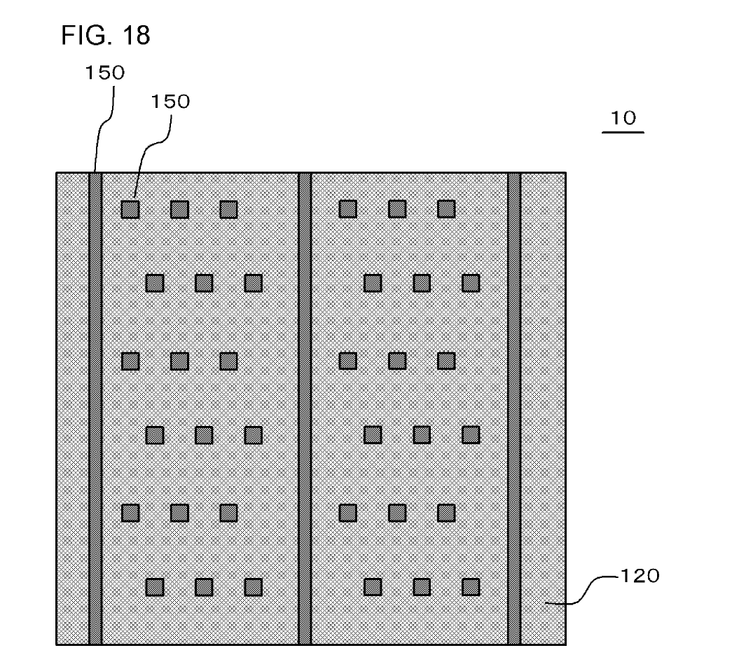

FIG. 18 is a plan view illustrating a layout of the optical angle change unit 150 of the light emitting device 10 according to Example 6, and corresponds to FIG. 3 of the embodiment. In this example, the optical angle change unit 150 is formed in the shape of a dot in addition to one extending linearly. Among them, the dotted optical angle change unit 150 is arranged between the adjacent linear optical angle change units 150 in the shape of a zigzag. However, a layout of the dotted optical angle change unit 150 is not limited to an example illustrated in this drawing. Furthermore, the dotted optical angle change unit 150 may be a pyramid, or may be a circular cone.

According to this example, the same effect as that of the embodiment is able to be obtained. In addition, the dotted optical angle change unit 150 is arranged between the linear optical angle change units 150, and thus even when light is incident in a direction parallel with the linear optical angle change unit 150, the same action as that of the embodiment occurs. For this reason, light extracting efficiency of the light emitting device 10 is able to be further increased.

As described above, the embodiments and the examples of the present invention are described with reference to the drawings, but the embodiments and the examples are an example of the present invention, and other various configurations are able to be adopted.

1. A light emitting device, comprising:
an organic functional layer which includes at least a light emitting layer;
a light transmissive electrode which faces one surface of the organic functional layer, and transmits light emitted by the light emitting layer;
a dielectric layer which faces a surface of the light transmissive electrode opposite to a surface facing the organic functional layer, and transmits the light emitted by the light emitting layer;
a light transmissive substrate of which a first surface faces a surface of the dielectric layer opposite to a surface facing the light transmissive electrode, and which transmits the light emitted by the light emitting layer, and emits the light from a second surface opposite to the first surface; and
an optical angle change unit of which at least a part is positioned in the dielectric layer, and which decreases an incident angle of light incident on the dielectric layer with respect to the first surface.

2. The light emitting device according to claim 1,
wherein a refractive index of the dielectric layer is greater than or equal to a refractive index of the light transmissive electrode.

3. The light emitting device according to claim 1,
wherein the optical angle change unit extends linearly in a first plane,
a part of a side surface is in contact with the light transmissive electrode in a second plane orthogonal to the first plane, and
at least a portion in contact with the light transmissive electrode has conductivity.

4. The light emitting device according to claim 3,
wherein the light transmissive electrode is continuously formed on the dielectric layer and on the optical angle change unit.

5. The light emitting device according to claim 3,
wherein the dielectric layer includes a concave portion in a surface in contact with the light transmissive electrode,
the light transmissive electrode is formed along the dielectric layer including an inner surface of the concave portion, and
a portion of the optical angle change unit positioned in the dielectric layer is disposed on the light transmissive electrode in the concave portion.

6. The light emitting device according to claim 3,
wherein the optical angle change unit is formed of a conductive material.

7. The light emitting device according to claim 1,
wherein an angle of a side surface in at least a tip portion of the optical angle change unit is changed to be closer to a direction parallel with the light transmissive substrate toward the light transmissive substrate in a second plane.

8. A light emitting device, comprising:
an organic functional layer which includes at least a light emitting layer;
a light transmissive electrode which faces one surface of the organic functional layer, and transmits light emitted by the light emitting layer;
a dielectric layer which faces a surface of the light transmissive electrode opposite to a surface facing the organic functional layer, and transmits the light emitted by the light emitting layer;
a light transmissive substrate of which a first surface faces a surface of the dielectric layer opposite to a surface facing the light transmissive electrode, and which transmits the light emitted by the light emitting layer, and emits the light from a second surface opposite to the first surface; and
an optical angle change unit of which at least a part is positioned in the dielectric layer, and at least a part of a side surface is inclined in a direction facing the light transmissive substrate, and which reflects light by the side surface.

9. (canceled)

10. (canceled)

11. A light emitting device, comprising:
an organic functional layer which includes at least a light emitting layer;
a light transmissive electrode which faces one surface of the organic functional layer, and transmits light emitted by the light emitting layer;
a dielectric layer which faces a surface of the light transmissive electrode opposite to a surface facing the organic functional layer, and of which a refractive index and a film thickness are greater than a refractive index and a film thickness of the light transmissive electrode;
a light transmissive substrate of which a first surface faces a surface of the dielectric layer opposite to a surface facing the light transmissive electrode; and
an optical angle change structure of which at least a part is positioned in the dielectric layer, and which decreases an incident angle of light incident on the dielectric layer with respect to the first surface,
wherein the optical angle change structure is substantially dot-shaped.

12. A light emitting device, comprising:
an organic layer which includes at least a light emitting layer;
a light transmissive electrode which faces one surface of the organic layer, and transmits light emitted by the light emitting layer;
a dielectric layer which faces a surface of the light transmissive electrode opposite to a surface facing the organic layer, and of which a refractive index and a film thickness are greater than a refractive index and a film thickness of the light transmissive electrode;
a light transmissive substrate of which a first surface faces a surface of the dielectric layer opposite to a surface facing the light transmissive electrode; and
an embedded member of which at least a part is positioned in the dielectric layer, which is formed of a material different from a material of the dielectric layer, and of which at least a part of a side surface is inclined,
wherein the embedded member is substantially dot-shaped.

13. A light emitting device, comprising:
an organic functional layer including a light emitting layer;
a light transmissive electrode that transmits light received from the light emitting layer, and faces a surface of the organic functional layer;
a dielectric layer that transmits light received from the light emitting layer, and faces a surface of the light transmissive electrode opposite a surface that faces the organic functional layer;
a light transmissive substrate having a first surface that faces a surface of the dielectric layer opposite to a surface facing the light transmissive electrode, the light transmissive substrate transmitting the light emitted by the light emitting layer and emitting the light from a second surface opposite the first surface; and
a material at least partially embedded in the dielectric layer, wherein the material decreases an incident angle of light incident on the dielectric layer with respect to the first surface, wherein the material is arranged in at least one of regular intervals and intervals different from that of other parts.

14. The light emitting device of claim 13, wherein the material at least one of extends linearly and is dotted on the dielectric layer.

15. The light emitting device of claim 14, wherein the dotted pattern comprises a plurality of substantially dots formed of the at least partially embedded material, in a zigzag configuration.

16. The light emitting device of claim 13, wherein the material is embedded so as to have a substantially conical profile.

17. The light emitting device of claim 13, wherein a profile of the material has a shape such that a first side surface is different from a second side surface.

18. The light emitting device of claim 17, wherein the shape is such that the first side surface is more inclined than the second side surface.

19. The light emitting device of claim 13, wherein the material comprises a conductive material.

20. The light emitting device of claim 13, wherein the material comprises one or more of a metal, a conductive paste and graphene.
